(19) United States
(12) Patent Application Publication
(10) Pub. No.: US 2006/0201740 A1
(43) Pub. Date: Sep. 14, 2006

(54) Pot-plant-shaped loudspeaker cabinet

(76) Inventor: Chih-Yuan Hsueh, Tauyuan Hsien (TW)

Correspondence Address: Chih-Yuan Hsueh, 9F., No. 37, Dongsing Road, Xinyi District, Taipei City, 110, TW

(21) Appl. No.: 11/077,678

(22) Filed: Mar. 14, 2005

(51) Int. Cl. A47B 81/06; H05K 5/00

(52) U.S. Cl. 181/199; 181/148

(57) ABSTRACT

A pot-plant-shaped loudspeaker cabinet mainly includes a flowerpot-shaped and open-topped hollow enclosure, at least one speaker received in the enclosure, a cover closing a top opening of the enclosure, a decorative pot plant fixed to the cover and including a plurality of optical fibers and a light source connected to roots of the optical fibers, and a wireless transmission device. Sound apertures are provided on the enclosure and the cover in different patterns to facilitate diffusion of sounds emitted from the speaker. The optical fibers upward guide light rays emitted from the light source to create changes in brightness and color of the emitted light rays. The wireless transmission device includes a transmitter unit associated with a sound signal source and a receiver circuit board connected to the speaker, enabling the speaker to receive sound signals either in a wired or a wireless manner.

### FIELD OF THE INVENTION

The present invention relates to a pot-plant-shaped loudspeaker cabinet, and more particularly to a loudspeaker cabinet in the shape of a pot plant that emits sounds and creates changes in light.

### BACKGROUND OF THE INVENTION

A loudspeaker is mainly used to convert current signals into sounds. This special function of restoring the current signals to sounds is important in the transmission of audio-visual data in the modern technological world. With the upgraded living standards, consumers demand more for loudspeakers providing superior sound effect.

Most of the conventional loudspeaker cabinets include a simple and generally rectangular box for at least one speaker to mount therein. The number and arrangement of speakers in the cabinet, the shape and internal space of the cabinet, and the design of frequency dividing circuit for the loudspeaker all involve in complicate and profound knowledge for the purpose of improving the sound quality of the loudspeaker. However, there are not attempts made to increase the added value of the conventional loudspeakers.

It is therefore tried by the inventor to develop a pot-plant-shaped loudspeaker cabinet to eliminate drawbacks existed in the conventional loudspeakers having a monotonous square cabinet.

### SUMMARY OF THE INVENTION

A primary object of the present invention is to provide a pot-plant-shaped loudspeaker cabinet having a flowerpot-shaped and open-topped hollow enclosure, at least one speaker received in the enclosure, a cover rested on and closing a top opening of the enclosure, and a decorative pot plant fixed to the cover. Sound apertures are provided on a wall of the enclosure and around a central hole of the cover in different patterns to facilitate diffusion of sounds emitted from the speaker. When the speaker receives current signals, sounds are emitted from the speaker. The pot-plant-shaped loudspeaker cabinet not only provides the basic function of emitting sounds, but also functions as a decoration to create a pleasant visual effect.

Another object of the present invention is to provide a pot-plant-shaped loudspeaker cabinet having a decorative pot plant fixed thereto. The decorative pot plant includes a plurality of optical fibers that upward guide light rays emitted from a light source below the optical fibers to create changes in brightness and color of the emitted light rays, and thereby effectively stimulate consumer's visual sensation.

A further object of the present invention is to provide a pot-plant-shaped loudspeaker cabinet having a wireless transmission device to enable wireless transmission of sound signals between the speaker in the loudspeaker cabinet and a related sound source. Therefore, the pot-plant-shaped loudspeaker cabinet may be positioned at different positions depending on actual need in interior decoration without being restricted by the wiring and location of the sound source.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a pot-plant-shaped loudspeaker cabinet according to an embodiment of the present invention;

FIG. 2 is an assembled sectional view of the pot-plant-shaped loudspeaker cabinet of FIG. 1;

FIG. 3 is an assembled perspective view of the pot-plant-shaped loudspeaker cabinet of FIG. 1; and

FIG. 4 is an operable circuit diagram for the present invention.

### DETAILED DESCRIPTION OF THE PREFERRED EMBODIMENTS

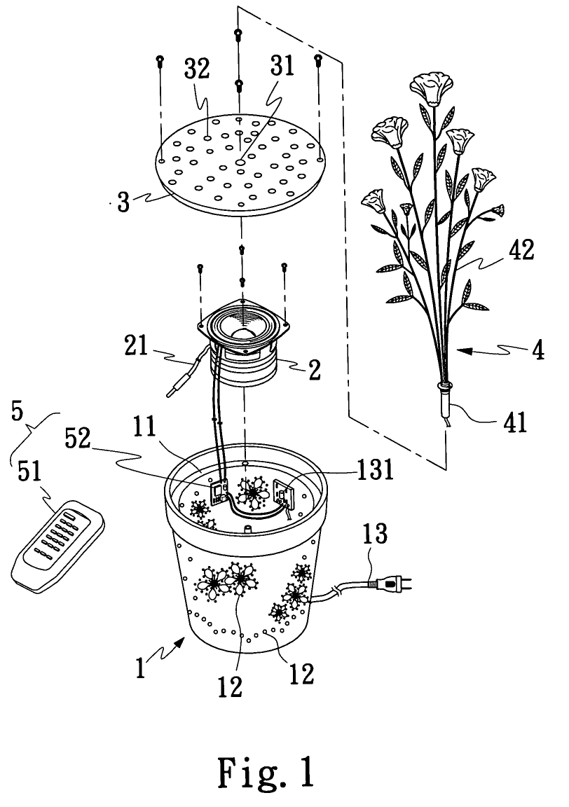

Please refer to FIG. 1 that is an exploded perspective view of a pot-plant-shaped loudspeaker cabinet according to an embodiment of the present invention. As shown, the pot-plant-shaped loudspeaker cabinet of the present invention mainly includes a flowerpot-shaped enclosure 1, at least one speaker 2, a cover 3, a decorative pot plant 4, and a wireless transmission device 5.

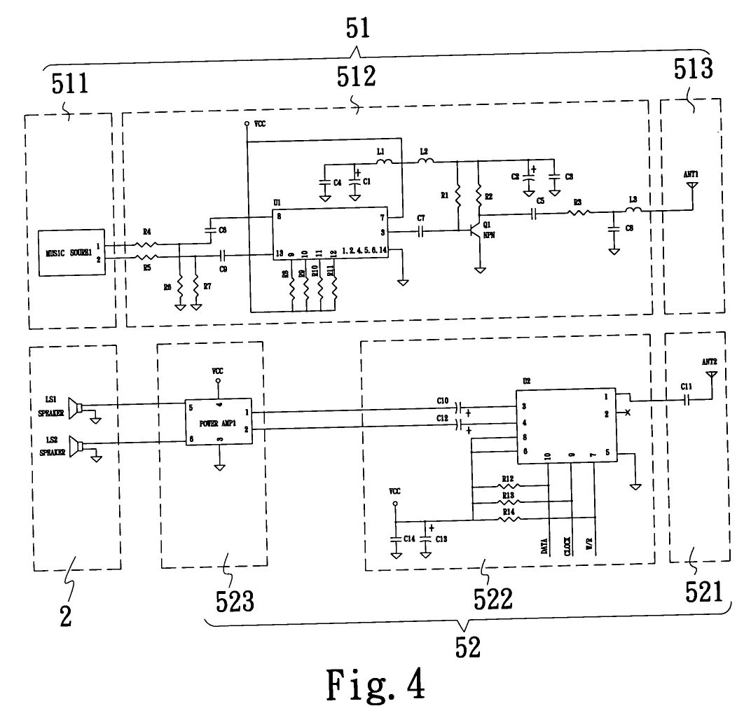

The flowerpot-shaped enclosure 1 is an open-topped hollow container having a radially inward extended annular flange 11 formed around a top opening thereof, and a plurality of first sound apertures 12 arranged on a wall of the enclosure 1 in different patterns according to actual need. The enclosure 1 is internally provided with a power supply device 131, which may be connected to an external alternating current power (not shown) via a power cord 13. The at least one speaker 2 is mounted in the flowerpot-shaped enclosure 1 with an input of the speaker 2 connected to a line 21 led to a sound source. The cover 3 is rested on the annular flange 11 around the top opening of the enclosure 1, and has a central hole 31 and a plurality of second sound apertures 32 provided around the central hole 31 according to actual need. The decorative pot plant 4 includes a plurality of optical fibers 42 and a light source 41 connected to roots of the optical fibers 42. Decorations, such as flowers, leaves, etc., are provided on the optical fibers 42 to complete the decorative pot plant 4. The wireless transmission device 5 includes a separate transmitter unit 51, which has a sound signal source 511 associated therewith (see FIG. 4), and a receiver circuit board 52 mounted in the flowerpot-shaped enclosure 1 to electrically connect to the at least one speaker 2.

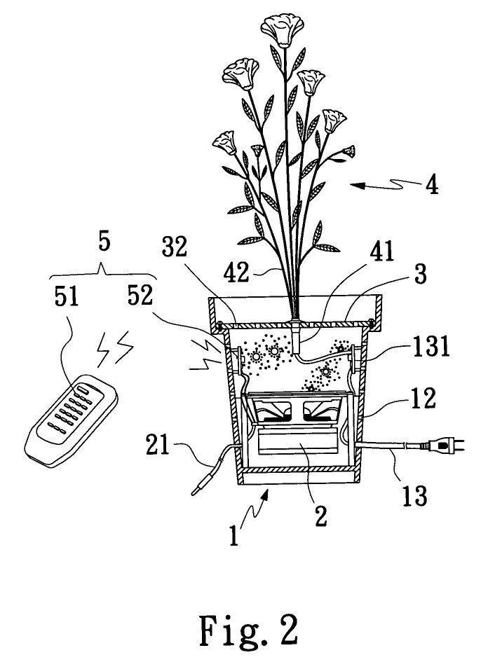

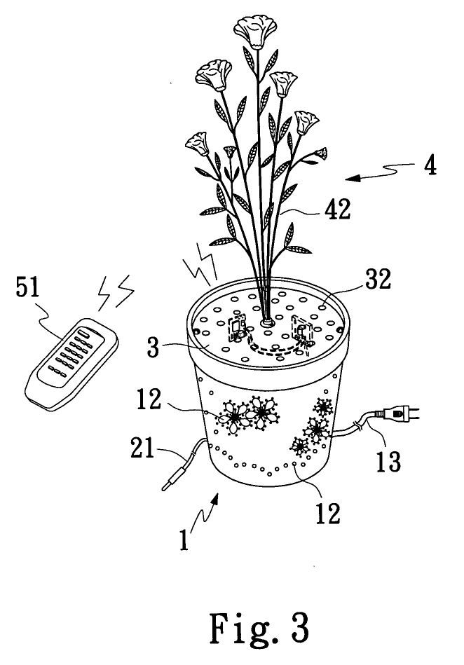

Please refer to FIGS. 2 and 3 that are assembled sectional and perspective views, respectively, of the present invention. The at least one speaker 2 is received in the flowerpot-shaped enclosure 1, and the cover 3 is closed onto the annular flange 11. The decorative pot plant 4 is fixed to the enclosure 1 by inserting the light source 41 in the central hole 31 on the cover 3. External alternating current power supplied via the power cord 13 is converted into proper direct current power by the power supply device 131 and supplied to electronic elements in the present invention. The at least one speaker 2 receives sound signals either via the sound source line 21 connected to a sound source or via the receiver circuit board 52 that wirelessly receives sound signals from the transmitter unit 51, and emits sounds that diffuse into air via the first and the second sound apertures 12, 32 on the wall of the enclosure 1 and the cover 3, respectively. The pot-plant-shaped loudspeaker cabinet effectively associates musical sounds and visual aesthetics to improve people's living environment.

The optical fibers 42 of the decorative pot plant 4 upward guide light rays emitted from the light source 41 to create changes in brightness and color of light and thereby effectively stimulate consumer's visual sensation.

FIG. 4 is an operable circuit diagram for the present invention. As shown, the transmitter unit 51 includes a sound signal source 511, an encoding and transmitting circuit 512, and a transmitting antenna 513. The encoding and transmitting circuit 512 consists of an integrated circuit U1, and related resistors R4, R5, R6, R7, R1, R2, R3, capacitors C6, C9, C4, C1, C7, C5, C2, C3, C8, inductors L1, L2, L3, and transistor Q1 mainly for receiving sound signals from the sound signal source 511, encoding the received sound signals, and outputting the encoded sound signals to the transmitting antenna 513, so that the encoded sound signals are outward transmitted in the form of radio wave. The receiver circuit board 52 mainly includes a receiving antenna 521, a decoding and receiving circuit 522, and a power amplifier 523. The decoding and receiving circuit 522 consists of an integrated circuit U2 and related resistors R12, R13, R14 and capacitors C10, C12, C13, C14. The radio-wave signals emitted from the transmitting antenna 513 are received by the receiving antenna 521 and sent to the decoding and receiving circuit 522 via a filter capacitor C11. The radio-wave signals are decoded at the decoding and receiving circuit 522 and then amplified by the power amplifier 523 before being sent to the at least one speaker 2 to emit sounds.

The pot-plant-shaped loudspeaker cabinet of the present invention is a combination of decoration and sounding apparatus, and has the function of providing changes in light and stimulating user's visual sensation, and is therefore novel, improved, and practical for use.

What is claimed is:

1. A pot-plant-shaped loudspeaker cabinet, comprising:
a flowerpot-shaped enclosure, which is an open-topped hollow container having a radially inward extended annular flange formed around a top opening of said enclosure for a cover having a central hole to rest thereon; said enclosure and said cover being provided on a peripheral wall and around the central hole, respectively, with a plurality of sound apertures, and said enclosure having a power supply device mounted therein and connected to an external alternating current power via a power cord;
a decorative pot plant, which is inserted in said central hole of said cover to form a decoration on said flowerpot-shaped enclosure;
a receiver circuit board, which receives radio wave emitted from a predetermined external transmitter unit and outputs sound signals; and
at least one speaker, which is mounted in said flowerpot-shaped enclosure with an input of said speaker electrically connected to an output of said receiver circuit board and a sound source line to enable receiving of sound signals either in a wired or in a wireless manner, and emitting of sounds.

2. The pot-plant-shaped loudspeaker cabinet as claimed in claim 1, wherein said transmitter unit consists of an encoding and transmitting circuit, and a transmitting antenna; said encoding and transmitting circuit receiving sound signals from a predetermined sound signal source, encoding the received sound signals, and outputting the encoded sound signals to said transmitting antenna, so that the encoded sound signals are outward transmitted in the form of radio wave; and wherein said receiver circuit board includes a receiving antenna, a decoding and receiving circuit, and a power amplifier; and said radio-wave signals emitted from said transmitting antenna being received by said receiving antenna, decoded at said decoding and receiving circuit, and then amplified by said power amplifier before being sent to said at least one speaker.

3. The pot-plant-shaped loudspeaker cabinet as claimed in claim 1, wherein said decorative pot plant includes a plurality of optical fibers and a light source connected to roots of said optical fibers; said light source being inserted in said central hole on said cover, and said optical fibers having decorations provided thereon.

4. The pot-plant-shaped loudspeaker cabinet as claimed in claim 2, wherein said decorative pot plant includes a plurality of optical fibers and a light source connected to roots of said optical fibers; said light source being inserted in said central hole on said cover, and said optical fibers having decorations provided thereon.
